(19) United States
(12) Patent Application Publication
(10) Pub. No.: US 2012/0081848 A1
(43) Pub. Date: Apr. 5, 2012

(54) Optical System Module For An Optical Measuring Device

(75) Inventors: Peter Wolf, Leinfelden-Echterdingen (DE); Owe Skultety-Betz, Leinfelden-Echterdingen (DE); Joeng Stierle, Waldenbuch (DE)

(73) Assignee: Robert Bosch GmbH, Stuttgart (DE)

(21) Appl. No.: 13/260,011

(22) PCT Filed: Jan. 27, 2010
(86) PCT No.: PCT/EP2010/050896

§ 371 Date: Dec. 19, 2011

(30) Foreign Application Priority Data
Mar. 23, 2009 (DE) 10 2009 001 727.

(51) Int. Cl. H05K 7/00

(52) U.S. Cl. 361/679.01

(57) ABSTRACT

An optical system module for an optical measuring device, especially a laser rangefinder, includes an optical system support, a display and a display holder, the display holder and the display being designed such that they embrace the optical system support between its axial end zones and that they have corresponding connecting elements detachably interconnecting them.

The present invention relates to an optical system module for an optical measuring device, especially a laser rangefinder, comprising an optical system support, a display and a display holder. Furthermore, the present invention relates to a display holder for such an optical system module and to an optical measuring device which is equipped with such an optical system module.

### PRIOR ART

Optical measuring devices of the type described above are known in various embodiments and may be designed especially as laser rangefinders. For example, DE 10 2005 041 980 A1 discloses a laser rangefinder which is designed as a handheld device. Provided as a central element in the laser rangefinder is an optical system support, on which an electrooptical transceiver system is held. For this purpose, the optical system support has receptacles and fastening means for the optical and/or electronic components of the measuring device.

For instance, a lens holder with receptacles for a receiving optical system is provided integrally on the front region of the optical system support. Furthermore, a printed circuit board, comprising a laser diode with a collimator lens mounted in front of it for producing a laser beam and a light-sensitive receiving diode, is held on the rear side of the optical system support. The printed circuit board is positioned in the measuring device in such a way that the laser diode can emit the light beam through the transmitting optical system and the light-sensitive receiving diode is positioned at the focal point of the receiving optical system. To improve the measuring accuracy and to reduce measuring errors, the light paths for transmitting and receiving are arranged in parallel. As a result, external influences on the optical system support act on the two light paths equally.

The optical system support with the electrooptical transceiver system fixed thereto is mounted together with a display device, an input device and an energy supply device in a common housing. During operation, the laser rangefinder is actuated by way of the input device. Then, a laser beam is emitted from the laser diode onto an item from which the distance is to be measured. The point of light projected onto the item is concentrated on the light-sensitive receiving diode and evaluated by means of the receiving optical system. The distance value obtained by the measurement is output by way of the display device.

The display device is usually formed as a liquid crystal display and held behind a window on the housing of the laser rangefinder. In day-to-day use, the laser rangefinder is subjected to mechanical stresses, for example caused by shocks, which can lead to the display being damaged. For this reason, the displays are often fitted in a frame provided on the housing of the measuring device. Guides prevent displacement of the display parallel to the plane of the window. The display is also fixed in the frame from above, it being possible for springs which allow a deviating movement of the display within the frame if there is excessive pressure to be provided. However, this type of securing is complicated and demanding.

It is therefore an object of the present invention to provide an optical system module, a display holder and an optical measuring device that ensure simple mounting of the display and offer effective protection from damage.

### DISCLOSURE OF THE INVENTION

This object is achieved according to the invention by the display holder and the display being designed such that they enclose the optical system support between its axial end regions, and have corresponding connecting elements, by which they are releasably connected to one another.

The basic idea of the present invention is therefore to reduce the influence of mechanical loads on the display by it not being held on the housing of the measuring device but on the optical system support. As a result, mechanical influences that usually act on the measuring device via the housing are not transmitted directly to the display. Since the display holder and the display form an enclosure around the optical system support, the latter is protected from damage by mechanical influences by the components of an electrooptical transceiver system held thereon.

In an advantageous configuration of the invention, the display holder has a substantially U-shaped cross section and the display is connected to the free ends of the legs of the display holder. The U-shaped cross section is well suited for the enclosure of the optical system support, and a connection to the display can be easily established at the free ends of the legs. If the legs of the display holder extend as far as the upper side of the optical system support, a planar display can be fixed on the display holder in a simple way, in order to form the enclosure of the optical system support.

Alternatively or in addition, the display may also have a substantially U-shaped cross section, the display holder then being connected to the free ends of the legs of the display.

The connecting elements may expediently be designed for establishing a snap-in or clip connection, with the result that no additional fastening means or tools are required for the mounting.

In a preferred way, the display holder and/or the display are elastically formed in their connecting region. For example, the connecting elements may be provided on elastic arms, which are formed at the free ends of the U legs of the display holder and/or the display. Alternatively or in addition, the U legs of the display and/or the display holder as a whole may be elastically formed, and in particular consist of an elastic plastic. The elastic form in this case constitutes additional protection for the display, since forces acting on the measuring device are only transmitted in a weakened form to the display via the elastic connection. Furthermore, production tolerances can also be compensated by the elastic form.

In addition, on the optical system support on the one hand and the display holder and/or the display on the other hand there may be provided corresponding projections and clearances, which are in engagement with one another in order to fix the display holder with the display on the optical system support. This makes it possible in a simple way to prescribe a position in which the arrangement comprising the display holder and the display is fixed on the optical system support. In a further mounting step, the display may be attached to the display holder positioned in this way, in order to complete the enclosure for the optical system support.

In a further configuration of the invention it may be provided that a rubber sleeve is held on a front plate of the optical system support, corresponding connecting elements by which the rubber sleeve is held on the display holder and/or the display being provided on the rubber sleeve on the one hand and the display holder and/or the display on the other hand. The rubber sleeve can be used in a way known per se for sealing the insertion opening of the housing. In this case, the connecting elements may be designed such that mounting is possible without additional aids.

With regard to further configurations of the invention, reference is made to the dependent claims and the following description of an exemplary embodiment with reference to the accompanying drawing, in which:

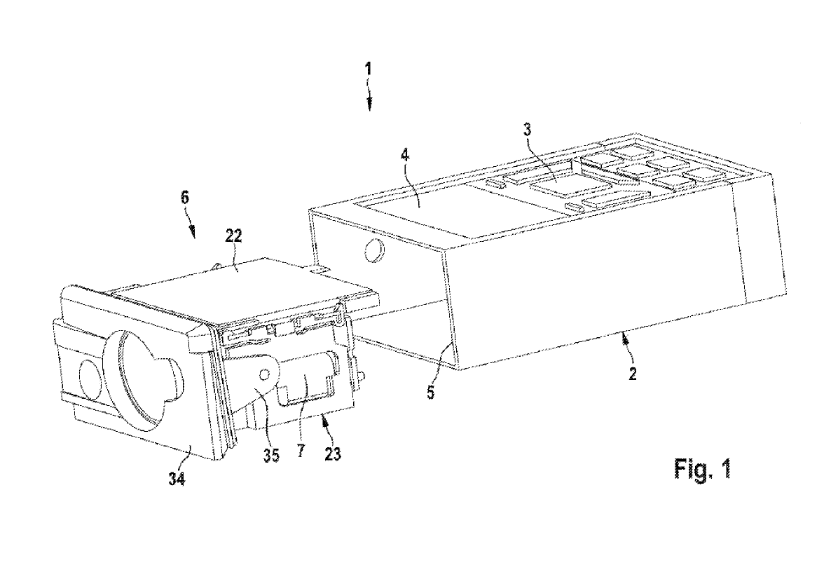

FIG. 1 shows a laser rangefinder according to the invention, comprising a housing and an optical system module, in a perspective view,

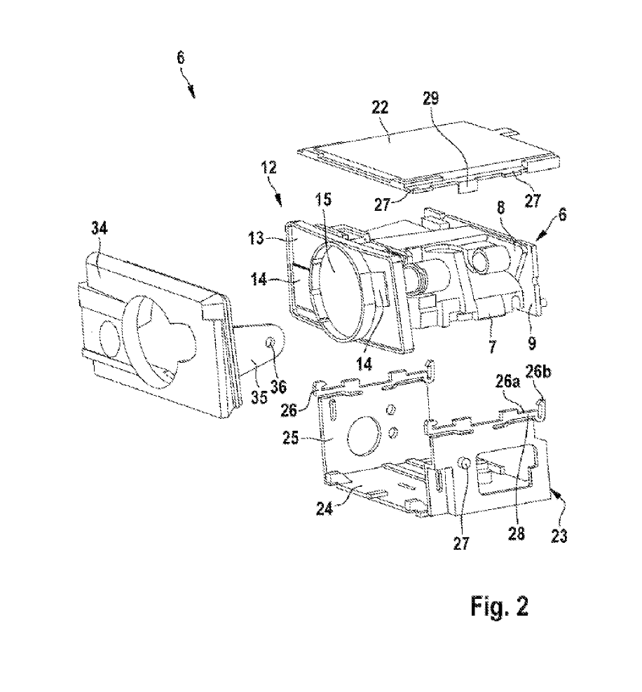

FIG. 2 shows the optical system module from FIG. 1, in an exploded representation,

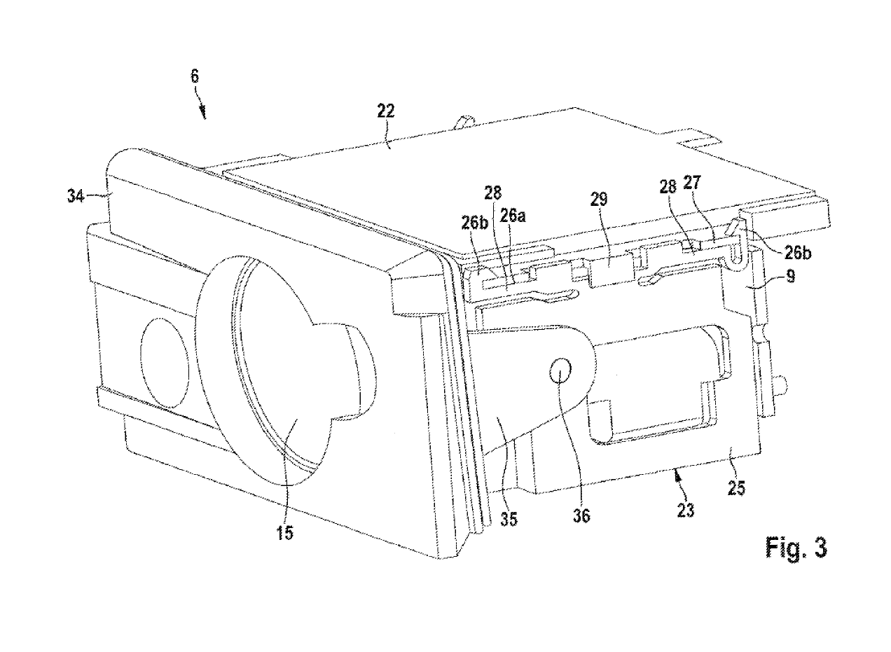

FIG. 3 shows the optical system module from FIG. 1 in the mounted state, in a perspective view,

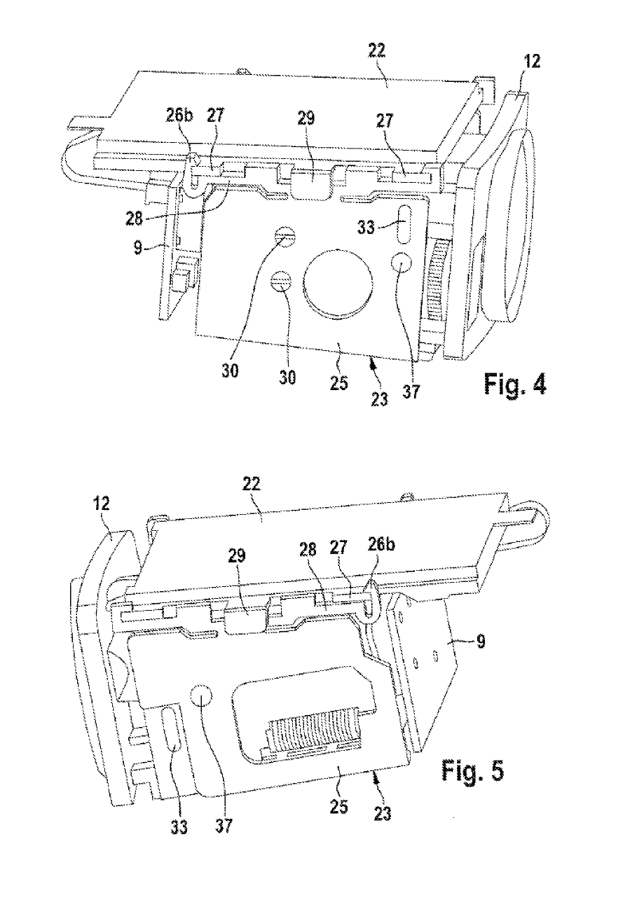

FIG. 4 shows the optical system module from FIG. 1 without a rubber sleeve, in a side view,

FIG. 5 shows the optical system module from FIG. 4 from the opposite side,

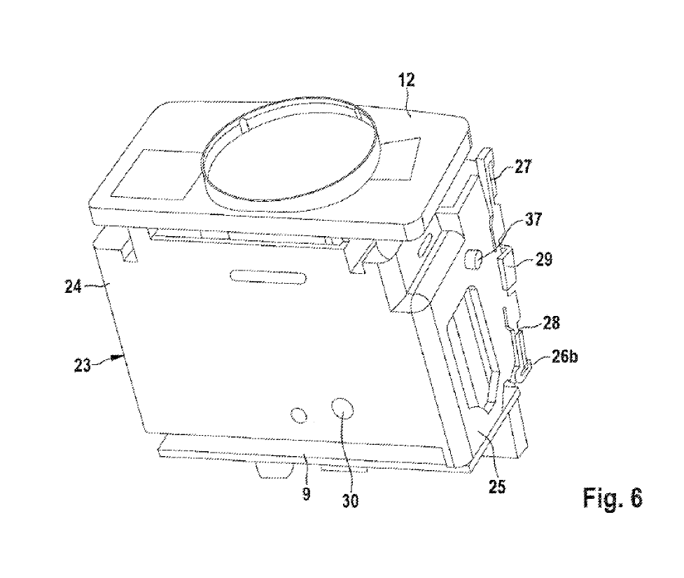

FIG. 6 shows the optical system module from FIG. 4, in a view obliquely from below,

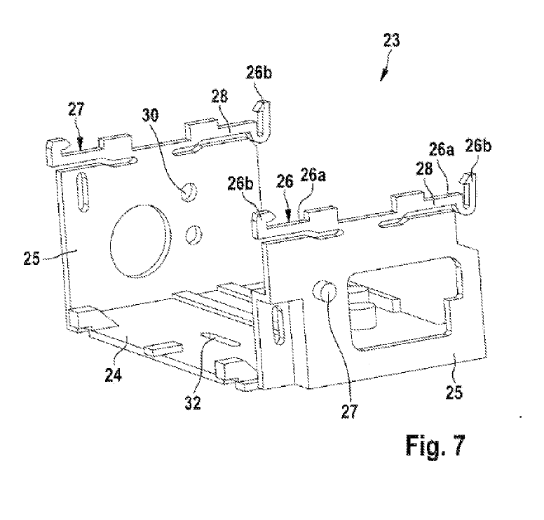

FIG. 7 shows a display holder of the optical system module from FIG. 1, in a perspective view,

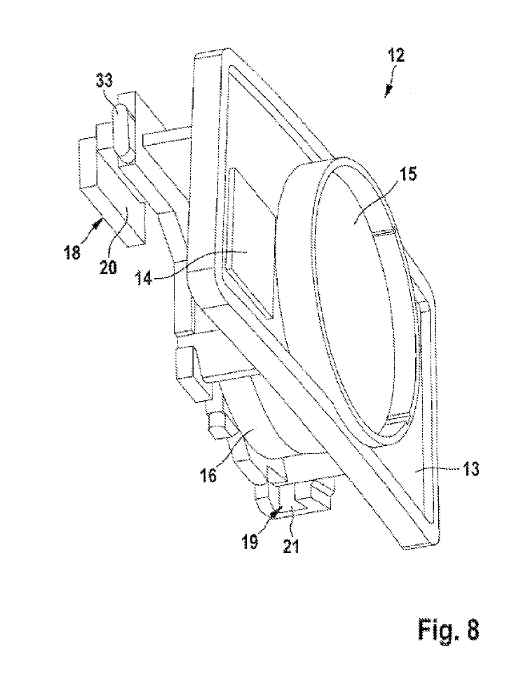

FIG. 8 shows a lens holder of the optical system module from FIG. 1, in a perspective view obliquely from above, and

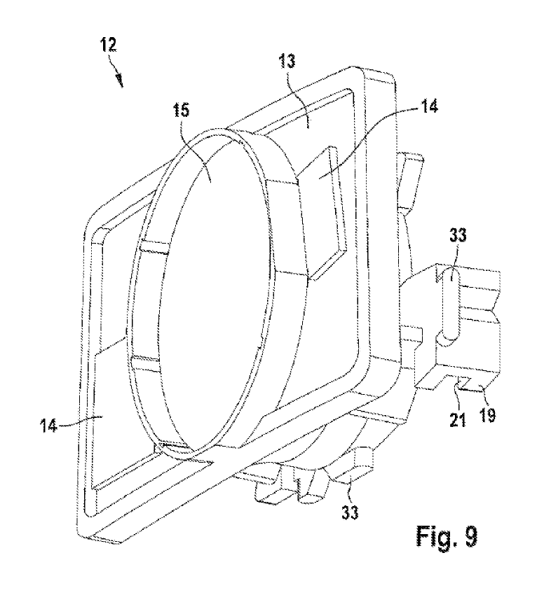

FIG. 9 shows the lens holder from FIG. 7, in a perspective view obliquely from below.

In FIG. 1, a laser rangefinder measuring device 1 according to the present invention is represented. The laser rangefinder measuring device 1 comprises a housing 2, which has on its upper side an operating device 3 and a viewing window 4. The measuring device 1 also includes an optical system module 6, which is inserted into the housing 2 through the open end face 5 thereof.

The optical system module 6 is represented in detail in

FIGS. 1 and 2 and comprises as a central element an optical system support 7, which serves the purpose of holding the optical and electronic components of the measuring device and has for this purpose corresponding fastening means and receptacles. For instance, the optical system support 7 has on its rear side a fastening flange 8, attached to which is a printed circuit board 9, which bears a laser diode for producing a laser beam and a light-sensitive receiving diode. Furthermore, provided in the fastening flange 8 are a number of openings, through which the optical components on the printed circuit board 9 can transmit light in the direction of the front side of the optical system support 7 and receive incoming light.

Provided on the front side of the optical system support 7 is a connecting flange, which serves substantially for the attachment of a lens holder 12.

The lens holder 12 comprises a front plate 13, which has two lateral exit panes 14 and a lens receptacle 15. The smaller exit pane 14, on the right in FIG. 2, represents the exit for a laser beam, while the larger exit pane 14, on the left, forms a window for an integrated target optical system. The central lens receptacle 15 serves for fastening a receiving lens and is surrounded by a tubular extension 16, which protrudes rearwardly in the direction of the optical system support 7, forms a shielding and in the mounted state lies against the connecting flange of the optical system support 7.

Provided on approximately diametrically opposite sides of the tube 16 on the rear side of the front plate 13 are two fastening elements 18, 19, by way of which the lens holder 12 is connected to the connecting flange of the optical system support 7. The fastening elements 18, 19 are designed such that they can be fitted onto the connecting flange of the optical system support 7 and then adhesively bonded to it. For this purpose, the fastening elements 18, 19 have corresponding recesses 20, 21, by way of which they can be pushed onto the connecting flange.

The optical system module 6 also includes a display 22, which is arranged on the upper side of the optical system support 7 and is fixed on the latter by a display holder 23. The display holder 23 is a structural part with a substantially U-shaped cross section, which consists of an elastic plastic. The display holder 23 has a base plate 24, which is placed on the underside of the optical system support 7, and two side walls 25, which rise up from the base plate 24 and extend in the direction of the display 22 on the opposite sides of the optical system support 7.

At their free ends, the two side walls 25 are releasably connected to the display 22 by snap-in or clip connections. Provided for this purpose on the lateral edges of the display 22 and on the upper edge regions of the two side walls 25 of the display holder 23 are connecting elements 26, 27 which correspond to one another and can be brought into engagement with one another. In actual fact, on each of the upper edges of the two side walls 25 of the display holder 23 there are formed two holding arms 28, which are elastically connected to the side walls 25 in the middle region thereof and extend outwardly parallel to the side walls 25. Respectively provided on the upper side of the holding arms 28 is a clearance 26a with a snap-in lug 26b assigned thereto, into which a correspondingly formed edge region 27 of the display holder 23 can be clipped. For the positioning of the display 22 on the display holder 23, the display 22 has on its longitudinal sides downwardly extending stop elements 29, which reach laterally over the side walls 25 of the display holder 23.

The display holder 23 also has a plurality of bores 30 for the optional fastening of further accessory parts, such as for example a Bluetooth module. Additionally provided on the display holder 23 are three longitudinal slits 32, into which corresponding webs 33 of the lens holder 12 engage. As a result, the display holder 23 is fixed in a prescribed position on the optical system support 7 and the lens holder 12.

The optical system module 6 also comprises a rubber sleeve 34, which covers over the lens holder 12 on its outer side. Provided on the transverse sides of the rubber sleeve 34 are fastening brackets 35, which have a through-hole 32. Provided on the side walls 25 of the display holder 23 are corresponding projections 27, onto which the fastening brackets 35 can be fitted in order to mount the rubber sleeve 34 on the display holder 23.

During operation, mechanical loads act on the laser rangefinder measuring device 1. They are dampened by the elastic display holder 23, with the result that the optical system support 2 with the electrooptical components held thereon is only exposed to small loads. Furthermore, the loads that act on the optical system support 7 are only transmitted in a dampened form to the display 22 via the resilient holding arms 28. The holding arms 28 thereby allow an elastic movement of the display 22, the movement transversely in relation to the longitudinal sides being limited by the stop elements 29.

1. An optical system module for an optical measuring device, comprising:
an optical system support,
a display, and
a display holder,
wherein the display holder and the display are designed such that they enclose the optical system support between its axial end regions, and have corresponding connecting elements, by which they are releasably connected to one another.

2. The optical system module as claimed in claim 1, wherein the connecting elements are designed for establishing a snap-in or clip connection.

3. The optical system module as claimed in claim 1, wherein the display holder has a substantially U-shaped cross section and the display is connected to the free ends of the legs of the display holder.

4. The optical system module as claimed in claim 1, wherein the display has a substantially U-shaped cross section and the display holder is connected to the free ends of the legs of the display.

5. The optical system module as claimed in claim 1, wherein the connecting elements are provided on elastic arms, which are formed at the free ends of the U legs of the display holder and/or the display.

6. The optical system module as claimed in claim 3, wherein the U legs of the display and/or the display holder are elastically formed.

7. The optical system module as claimed in claim 1, wherein on the optical system support on the one hand and the display holder and/or the display on the other hand there are provided corresponding projections and clearances, which are in engagement with one another in order to fix the display holder with the display on the optical system support.

8. The optical system module as claimed in claim 1, further comprising a rubber sleeve held on a front plate of the optical system support, corresponding connecting elements by which the rubber sleeve is held on the display holder and/or the display being provided on the rubber sleeve on the one hand and the display holder and/or the display on the other hand.

9. A display holder for attaching a display to an optical system support of an optical measuring device, wherein the display holder has a substantially U-shaped cross section and at its free ends has connecting elements for releasably attaching the display.

10. The display holder as claimed in claim 9, wherein the connecting elements are designed for establishing a snap-in or clip connection.

11. The display holder as claimed in claim 9, wherein the connecting elements are provided on elastic arms, which are formed on the free U legs of the display holder.

12. The display holder as claimed in claim 9, wherein the legs of the display holder are elastically formed.

13. The display holder as claimed in claim 9, wherein the display holder has a connecting mechanism for attachment to an optical system support.

14. The display holder as claimed in claim 9, wherein the display holder has a fastening means mechanism for the attachment of a rubber sleeve.

15. The display holder as claimed in claim 9, wherein the display holder has a fastening mechanism for connection to a housing of the optical measuring device, the fastening mechanism comprising a setting device by which the display holder is configured to be positioned in relation to the housing.

16. An optical measuring device, comprising:
a housing,
an optical system support, and
a display, wherein the optical system support is connected to the display and a display holder to form an optical system module as claimed in claim 1 and is inserted into the housing.

17. The optical system module as claimed in claim 6, wherein the U legs of the display and/or the display holder are made of an elastic plastic.

18. The display holder as claimed in claim 12, wherein the legs of the display holder are made of an elastic plastic.
